(19) United States
(12) Patent Application Publication
(10) Pub. No.: US 2004/0105228 A1
(43) Pub. Date: Jun. 3, 2004

(54) Electrical circuit board

(76) Inventor: Peter Leslie Moran, Alderley Edge (GB)

Correspondence Address: Andreas Grubert, Baker Botts L.L.P., One Shell Plaza, 910 Louisiana, Houston, TX, 77002, US

(21) Appl. No.: 10/705,105

(22) Filed: Nov. 11, 2003

(30) Foreign Application Priority Data
Nov. 13, 2002 (GB) GB 0226392.9
Jan. 14, 2003 (GB) GB 0300772.1
Apr. 9, 2003 (GB) GB 0308134.6

(51) Int. Cl. H05K 5/00

(52) U.S. Cl. 361/683

(57) ABSTRACT

A process for the manufacture of a electrical circuit board (1, 2a, 2b, 5a, 5b) is described in which a part of some or all of the conductors (5a) can be readily detached from the insulating substrate (1) of the board (1, 2a, 2b, 5a, 5b). This circuit board (1, 2a, 2b, 5a, 5b) allows pins (5b) or other interconnection devices to be fabricated as integral part of the board (1, 2a, 2b, 5a, 5b). This process allows a particularly high density of pin (5b) to be readily achieved and by definition the pins (5b) are automatically aligned to the remaining conductors (5a) on the circuit board (1, 2a, 2b, 5a, 5b).

### PRIORITY

This application claims foreign priority of Application No. 0226392.9 filed in Great Britain on Nov. 13, 2002; and Application No. 0300772.1 filed in Great Britain on Jan. 14, 2003; and Application No. 0308134.6 filed in Great Britain on Apr. 7, 2003

### TECHNICAL FIELD OF THE INVENTION

Electrical circuit boards are used simultaneously to mechanically hold and electrically interconnect a number of electronic components. From time to time it is found desirable to assemble a relatively small number of components onto a circuit board and then assemble this sub-assembly or module onto another larger board. The key benefit of this is that the small assembly has a fully defined function that can be tested prior to assembly onto the larger board. In order to facilitate the joining of the sub assembly to the larger board some form of connection or pinning arrangement is required. Such a concept is not new and so called mother and daughter boards are quite common.

The invention to be outlined here is concerned with a new way of providing this pinning or interconnection between the mother board and daughter board and in particular describes a method of manufacturing the daughter board such that the pins attached to the daughter board are an integral extension of tracks on the board.

### BACKGROUND OF THE INVENTION

Currently employed techniques for this interconnection include at one extreme a set of pins on one part and a mating socket on the other. These pins and sockets are usually supplied in the form of a plastic moulding containing stamped metal parts either in-moulded or clipped into the moulding. This arrangement allows the motherboard readily to be disassembled from the daughter board. An alternative is to provide pins on the daughter board that are attached by soldering and for these pins in turn to be soldered to the mother board using either through hole mounting or surface mounting techniques. In this case, such pins would be manufactured by stamping from solid sheet material and subsequently plated to provide a suitable surface finish for soldering. These pins need soldering to the daughter board. Whilst this is a simple process, it is not without issues such as flux removal and ensuring 100% solderability on a low cost process applied to a relatively high cost assembly. An alternative is to include solder in the pin. This does enable some of the cleaning issues to be addressed and can form a more reliable joint, but the inclusion of the solder is an expensive process and hence such pins are significantly more costly that non solder bearing pins.

The benefit of manufacturing such module is that it forms a very convenient unit for commercial activity. It can be fully specified and tested prior to assembly to the mother board and as such is a known good component in its own right. There is therefore a greater chance that the larger “mother” board will function correctly first time and that trouble shooting on a faulty board is easier. The motherboard then becomes an assembly of known functioning sub assemblies with each function being designed and tested by a different specialist supplier.

The choice of insulating material used for the motherboard is a technical decision based primarily on the environment in which the part will operate and the extent to which the insulator contributes to the functioning of the module. For simple non-demanding circuits an organic substrate is adequate. However if high frequency, high power or miniaturisation are a consideration then the use of a ceramic material is frequently necessary. If the environment is such that it is important to avoid any possible contaminants that could be associated with organic materials and could damage some of the components on the module, then it is often essential to use ceramic material.

The invention described here relates to an improved method for the fabrication of circuit boards in which the pins that are used to form the connection from the module to the motherboard are an integral part of the circuit board used to manufacture the module. The benefits of this invention are:—

1. Works well with ceramic

2. Elimination of the cost of the pin and the cost of assembly and subsequent cleaning

3. A higher density of pin can be achieved than is possible by stamping and subsequently clipping the stamped pin onto the board

4. The pin is automatically located correctly with respect to the tracking on the circuit board

5. Space saving on the daughter board

6. The pins can be irregularly spaced, of varying thickness and may be part of an irregularly shaped daughter board. This can be useful for circuits that carry a high current.

The integration of a pin onto a circuit board is not by itself new. The so-called direct bonding process in which a copper foil is bonded at high temperature to an oxide-based ceramic using an eutectic alloy does allow just such a benefit. However in this case the foil must be formed to shape prior to bonding and in general the board must be cut to final size prior to bonding. The pins then simply hang over the edge of the board. This process is described by Henning et al in U.S. Pat. No. 5,238,702. It is a feature of the present invention to support the overhanging pins to prevent distortion while the copper foil is bonded to the ceramic at in excess of 1000° C.

Techniques for forming integrated leads on organic circuit boards have been exploited in the so called Tape Automated Bonding technique where the insulating part of the circuit board is removed from under the circuit traces by laser ablation or chemical etching. These techniques work for polymeric based circuit boards since either the laser evaporates the polymer with significantly less energy than is needed to damage the copper of the circuit traces, or chemicals can be found that dissolve the polymer but do not attack the circuit traces to any significant extent. Neither of these techniques works with ceramic. The electrical traces of such circuits are attached to the polymer by gluing. The temperature used for curing this glue is typically 150° C. An expensive alternative is to use a thin film coating to provide the adhesion step for the conductor. In this case it is not necessary to elevate the temperature to form a bond since the energy of the deposition is adequate to provide the bond. This process is however extremely expensive. Various implementations of this technique are described in U.S. Pat. No. 4,965,702 and its references.

U.S. Pat. No. 4,500,029 describes a process that uses organometallic salts of palladium dispersed in a various organic adhesive binders. After deposition of the ink and drying or curing at temperature, the palladium can be activated and electroless copper deposited onto the dried ink. The deposited film of organometallic palladium is not itself electrically conductive and is used to provide a mechanism for the chemical deposition of the electrical traces and also the adhesion of the traces to the underlying circuit board. By choosing two different formulations for the binder, one ink can be made to have good adhesion and the other poor adhesion. In this way freestanding circuit traces can be formed not supported by the insulating part of the circuit board. The curing or drying of the palladium bearing ink is carried out at less than 350° C. Whilst adhesive based techniques have been shown to work on less demanding organic based insulators, they have not been successful on ceramic materials. The level of adhesion is generally too low, particularly after ageing. The reasons for choosing a ceramic substrate over an organic are given above.

### SUMMARY OF THE INVENTION

The invention described herein allows the individual boards to be fabricated as part of a larger panel or array of individual boards including the pins on ceramic. It also allows the ready inclusion of plated through holes at minimal cost. The geometry of the circuit board can be complex with fine features. There is no need to support the integrated leads. These are major economic benefits when compared with direct bond copper. The process is characterised by including a firing step in excess of 450° C., preferably above 500° C., in order provide a reaction between some part of the conductor and the ceramic or other inorganic substrate plus the use of selective deposition of at least some of the conductors. This reaction gives rise to a very high level of adhesion of the circuit conductors that is stable in the normal environmental conditions in which electronic circuits are required to operate. The selective deposition gives rise to high track density and there are no restrictions on the circuit geometry. A very large number of isolated tracks and pads can be included on the board. In practice the track geometry can be significantly finer than can be achieved with direct bond copper and the pin pitch is much finer and versatile than can be achieved with stamping. Parts that have been realised by this process show excellent high temperature performance (in excess of 350° C.), outstanding adhesion (in excess of 5 N/mm) and either do not require the use of any materials potentially harmful to the environment such as the formaldehyde used in electroless copper deposition or only minimal amounts of materials such as copper etchants.

The invention provides a process for the manufacturing of an electrical circuit board complete with some conductors that are in part attached to the circuit board and in part detached from the board comprising the following steps:

a) forming a structure that consists of an electrically insulating substrate processed to contain two mutually exclusive regions, these regions touching to provide electrical continuity over the insulator where required, wherein one region is such that metal can be deposited on to it and be permanently bonded to the substrate and the other region is such that metal can be deposited on to it but the bond to the substrate is only temporary, the one region being fired at a temperature in excess of 450° C. to form a bond and the insulator is an inorganic material capable of withstanding this firing temperature,

b) metal is then deposited selectively onto the two regions,

c) the bond is released in the other region,

d) the board is then broken into individual panels to leave the circuit board with a pattern of conductors in some places permanently bonded to the insulator and part of some of the conductors no longer attached to the substrate.

The insulator will allow metal to be deposited and permanently bonded to it and a coating material can be applied selectively to the insulator with the property that metal can be deposited on it but the bond is temporary. The insulating substrate will allow metal to be deposited on it but the bond is only temporary and a coating material can be applied selectively to the insulating substrate with the property that after firing at a temperature in excess of 450° C. it will allow metal to be deposited onto it and the bond is permanent. The conductors may not be deposited directly onto the insulating substrate. The one region can be formed by coating with a material that is subsequently fired at a temperature in excess of 450° C. to allow metal to be deposited on it and is such that the bond is permanent and the other region is formed by coating with a material that will allow metal to be deposited on it and is such that the bond is temporary. The one region can be formed by coating with a material that is subsequently fired at a temperature in excess of 450° C. that will allow metal to be deposited on it and is such that the bond is permanent and the other region is formed by coating both the insulating substrate and the one region with a material that will allow metal to be deposited on it and is such that the bond is temporary where the temporary coating is in contact with the insulating substrate. The bond can be permanent where the metal is deposited onto the coating that is used to promote permanent adhesion. The conductors that are permanently bonded to the insulating substrate can be formed into a circuit pattern before the formation of the temporarily adhered layer. The insulating substrate can be a ceramic material. The material used to form a permanent bond between the insulating substrate and deposited conductor can be a thick film conductor. The material used to form a permanent bond between the insulating substrate and deposited conductor can be formed by a metallorganic material. The thick film material can be one of silver based or gold based. The metallorganic material can be one of silver based, gold based or platinum based. The other region can be formed by coating with a plastic material that is blended with metallic particles so that it is electrically conductive after drying or curing. The plastic material can be removed by dissolution in a suitable etchant or solvent in order to release the bond of the conductor to the insulating substrate at that point. The material used to coat the substrate in the other region can be based on electroless metal deposition. The metal can be one of copper, nickel, silver or gold. The material used to coat the insulating substrate in the other region contains a metallorganic salt and the salt can be heated to reduce the salt to the metal. The metal can be one of gold, silver, platinum, palladium or copper. Some part or parts of some of the conductors may not be bonded to the circuit board. The non-bonded region can be outside the boundary of the circuit board. The insulating substrate on which the integrated leads are formed can be a pre-manufactured circuit board. The pre-manufactured circuit board may have outer layers and the process can be applied to outer layers of the board. The process may further comprise the step of forming a circuit board in which some part or parts of at least one of the circuit conductors are not bonded to the insulating substrate of the circuit board. Part of at least one of the conductors may overhang the edge of the insulating substrate.

### BRIEF DESCRIPTION OF THE DRAWINGS

The invention will now be described with reference to the accompanying drawings in which:

FIG. 1 illustrates a circuit board of the invention,

FIG. 2 shows one formation of circuit and pins on the board of FIG. 1,

FIG. 3 shows an alternative formation of circuit and pins on the board of FIG. 1,

FIG. 4 shows the circuit board of FIG. 3 with the resist removed,

FIG. 5 shows the circuit board of FIG. 4 after etching, and

FIG. 6 shows the circuit board of FIG. 5 on completion of the process.

### DESCRIPTION OF THE PREFERRED EMBODIMENTS

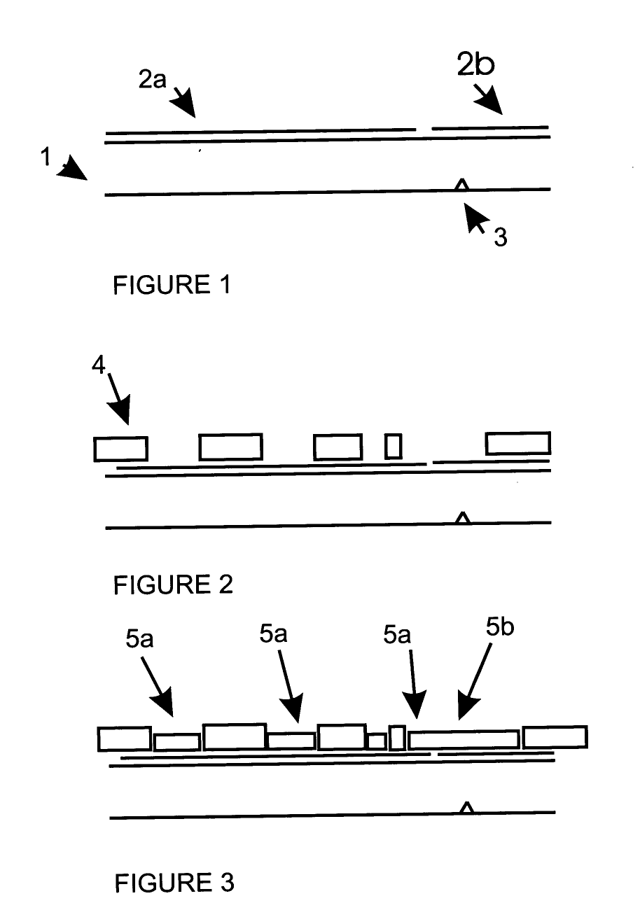

The starting point for this invention is an electrically insulating sheet of inorganic material in which there are two distinct regions. With reference to FIG. 1 the insulator is member 1 and the regions are defined as member 2a and member 2b. Member 2a is characterised by the fact that it can be can accept the deposition of metal that will be well and permanently adhered to member 1. Member 2b is characterised by the fact that it is able to accept the deposition of metal that is either well adhered to member 1 but may be released from member 1 by suitable processing, or is adequately well adhered to member 1 to withstand the subsequent processing activity but not so well adhered that it cannot readily be released from member 1 after processing without damaging the conductors or insulator. The definition of the term permanent is equivalent to the adhesion and longevity required for the bonding of the conductor of an electrical circuit board to the insulator. The definition of the term temporary is that either the initial bond is strong but after suitable treatment becomes weak or non-existent or that the strength of the bond is sufficient to allow the board to be manufactured without damage to the conductors but weak enough to allow the conductor to be detached from the substrate without damaging the conductors or insulator. This invention is not limited by the exact deposition pattern of members 2a and 2b. The regions may be just under the tracks of the circuit board or more widely over the circuit board. It is not necessary for the regions to extend over the entire surface of member 1.

Members 2a and 2b need to touch in order to provide electrical continuity from the circuit to the pin. In one situation where members 2a and 2b are mutually incompatible they will require to be formed in separate regions and overlap to the smallest practical extent. Alternatively, members 2a and 2b may be compatible and one or the other can be freely deposited on top of the other without compromising the functionality of either.

At some stage a line of weakness may be introduced. This is shown as member 3. This line of weakness is shown as being on the rear of the circuit board but may equally well be on the top surface. The line of weakness is used to fracture the boards into individual circuits at a subsequent stage. Although the step of separating out the individual boards is essential, the particular method used is not critical. This process could also be carried out after fabrication of the board in which case it could be that the board is cut out by routing.

The circuit and pins are now formed as shown in FIG. 2. Member 4 is a coating in which openings will be formed that correspond to the tracks of the circuit board and the integrated pins. Such techniques are well known in the industry and the coating could conveniently but not necessarily be a photosensitive coating. By exposing the photosensitive coating to light through a mask and then developing or washing out the resist, a pattern of openings down to members 2a and 2b is formed in the resist as shown in FIG. 2. Alternatively, the coating could be applied by a printing or other selective deposition process, in which case the openings are defined at the same time as the coating is deposited. The particular method by which the deposition mask is defined is not critical to the invention.

The openings in the mask form the channels into which metal can be deposited to form the conductors of the circuit board and the pins. The easiest way of providing this conductor is for members 2a and 2b to be electrically conductive and to electroplate metal in the openings of the resist. It is obviously necessary to ensure that the deposition pattern of members 2a and 2b are such as to provide an electrically conductive path to all tracks and pins. However, the invention is not limited by this step. An alternative would be to make members 2a and 2b susceptible to accepting a suitable catalyst and to fabricate the conductors by electroless deposition such as nickel or copper. Alternatively, a combination of both electroless and electroplating is possible. This step is shown in FIG. 3 in which the conductor and pin are represented as member 5a and member 5b respectively.

However the conductors and pins are formed, the key element is that the conductors of the circuit board are deposited on member 2a and the pins are deposited on member 2b. The particular method of and material used for the fabrication are not limiting factors of the invention. At some stage in the process members 2a and 5a are bonded to member 1 by a firing step in excess of 450° C. Depending on the precise implementation, member 2a can be formed by a separate coating that is bonded to member 1 and member 5a is deposited on member 2a. Alternatively, member 2a is formed by a processing or coating step and the deposited conductor 5a is deposited on 2a. Both are then bonded to member 1 simultaneously by the firing step.

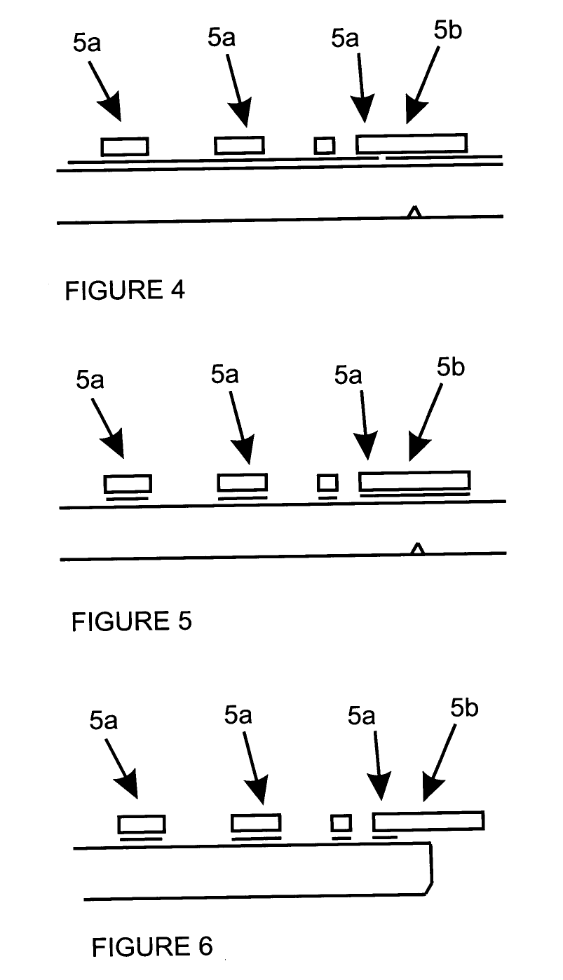

With reference to FIG. 4, the resist 4 has been removed by the usual processes employed for the resist. This process will usually be described by the vendor of the resist. If members 2a and 2b are electrically conductive and extend beyond the confines of the tracks, the next step is to remove those elements of members 2a and 2b not covered by the metallic conductor 5. This can be achieved by any appropriate means but would typically be by dissolution in an appropriate etchant. This state is shown in FIG. 5. The board now consists of the insulating substrate 1 with various conductors 5a and pins 5b bonded to the substrate by members 2a and 2b respectively.

The board is now completed by causing member 2b to release from member 1.

By fracturing the panel of individual boards along the line of weakness 3 the individual units can be broken out from the panel. It will be noticed that the conductors 5a of the circuit board are still well attached to the substrate (1) but that the pins 5b are attached to a conductor 5a but that the other end is no longer attached to the insulator 1 and in this example overhang the edge of the circuit board. These pins can be formed for instance into the shape commonly known as a “gull wing” pin and this is shown in FIG. 6. Such a board is ready to have components placed on it and soldered in situ. The whole module is then soldered to the motherboard.

There are a number of variations of this process which do not affect the validity of the invention but which may enhance the functionality of its use. For instance the circuit board could be double sided with or without through connections. In such a case, holes would be drilled either prior to the processing described here or just after the fabrication of regions 2a and 2b. In this latter case the holes would also need treating to ensure that the conductive layer that is well adhered to the insulator also extends down the holes. The circuit board could be a multilayer board where the inner layers have been formed previously and bonded together. The processing described here would then be applied to the outer layers of the board.

Although the process has been described as releasing the conductor 5b from layer 2b after removing the mask 4, it is also valid to release the conductor 5b from layer 2b at the same time as removing layer 4. The release of conductor 5b from the insulator in the region 2b may be carried out in two distinct ways. Firstly, by suitable processing, the region 2b may cease to have any adhesive or bonding characteristics. Alternatively, it is possible to remove layer 2b in its entirety.

The line of weakness 3 may be introduced in a number of ways. It could be on the back of the insulator or the front of the insulator. If it is on the back, it could be introduced either before the conductors are deposited or after. Also, if it is on the back, it could be carried out by cutting through insulator whilst taking care not to damage the conductor.

The process so far has been described by fabricating the conductors of the circuit board at the same time as the partially attached pins. There are however, circumstances in which it might be desirable to add pins to a circuit that has already been fabricated but has not yet been detached from the panel in which it was made. In order to achieve this, the spacing between the circuits must be such as allow room for the pins. The point where the pins are to be connected to the circuit board would be a suitable pad on the circuit. The circuit board would then be coated with an electrically conductive layer that had the properties described previously. This coating could be either selective or cover the entire circuit board depending on the choice of coating. The remainder of the process would the follow the example in which the circuit is formed at the same time as the pins but would only form the pins plus the contact region. In some circumstances some of the circuit might be also be built up to provide conductors with lower track resistance.

The preferred embodiment uses alumina ceramic as the insulating substrate. The particular choice of material is not critical to the application and Coors ADS96R is quite suitable. The substrate is pre-drilled to form holes that will become the through connections from front to back, and lines of weakness are scored in the substrate preferably but not essentially on the back.

The region that is well adhered is formed by printing and firing a thick film conductor onto both surfaces and in the through holes. The conductor coats as a minimum the region where the tracks will be defined. It does not extend into the region where the temporarily adhered region is to be formed. There are numerous suitable thick film pastes but one appropriate material is coded 9562 and is manufactured by ESL Inc. This should be printed and fired according to the manufacturer's instructions. Typical firing temperatures are in excess of 800° C. Although a conductor in its own right, the thick film conductor does not have adequate strength to form the pins required for this invention. An alternative to the thick film material is to use a metal-organic gold coating. This too would be fired at a temperature in excess of 800° C.

Next, the temporary layer is deposited on the substrate. The region to be coated is as a minimum under the pins but could extend beyond this area. A suitable material is an electrically conductive silver paint sold by RS Components. This can be simply painted on in these regions and dried. Alternatively, it can be screen-printed. Such printing materials are available from several vendors. The interface region should be kept as small as possible. However, for practical purposes it is essential that the two regions overlap where continuity is required from circuit conductor to integrated pin. The paint is an electrically insulating plastic material that has some adhesive properties blended with silver particles such that it is electrically conductive after drying. It does not cure and can be removed by dissolution in various solvents.

Whatever the pattern employed for the various depositions, it is essential in this embodiment that all the regions should be electrically connected.

A photosensitive coating is then applied. Again, there is a wide choice of suitable materials but the Alpha series sold by Elga Europe is appropriate. This material is laminated onto the surfaces and exposed to ultraviolet light through a mask. It is then developed to form the openings in the resist. The parameters for this step are contained in the manufacturer's data sheets.

Copper is now electroplated in the openings of the resist. The process is continued until the desired thickness of copper has been obtained.

The resist is now stripped according to the manufacturer's data sheets. In some cases this may well remove or release the temporary adhering coating. This is not important.

The thick film material not underneath the conductors is removed by etching. A suitable fluid is that sold by Transcene Inc as a silver etchant. This material does tend to discolour and tarnish the copper tracks, and so in some circumstances it may be necessary to re-coat the copper tracks with resist and expose and develop the resist to leave a protective film on the conductors. This will prevent the surface of the conductors from tarnishing during etching. The resist is then removed according to the manufacturer's instructions.

The silver paint is completely removed by dissolving in acetone. This can take place either before or after the previously defined step.

In order to complete the module, the individual circuits are fractured out from the panel by breaking along the lines of weakness. This leaves the pins in the plated copper detached from the substrate and ready for either assembling using through hole techniques or forming into a suitable shape for surface mounting. A key benefit of this process is that the pins can extend beyond the area of the insulator of the board.

It will be appreciated that although the invention has been described with reference to pins overhanging the substrate, it is also possible that the pins can be formed in the interior of the circuit board and simply bent away from the board.

The process has been described in relation to a silver-based thick film conductor. Alternatives could be gold based or copper based.

Another embodiment of this process is to use as the starting point a panel containing one or more circuits. These circuits would be substantially finished but would not yet have been removed from the panel in which they were fabricated. The insulator could be a ceramic material such as 96% alumina. The conductor could be a plated copper or a screen printed and fired silver, copper or gold based material. The panel is then coated with electroless copper. With correct processing, the electroless copper will adhere well to the conductors of the circuit board but have only minimal adhesion to the insulating material. Certain metallorganic coatings can be deposited and fired to take the place of the electroless copper. The board is then coated with the photoresist and the remainder of the process follows as in the previous examples. The firing step would be included in the initial deposition process used to form the circuit.

There is a wide range of practical alternatives to those described here that are suitable for implementing this invention. The insulating material could be any specification of ceramic and in particular alumina ceramic (such as 99.5% grade), a glass ceramic, glass or aluminium nitride or a combination or blend of these materials. The conductor could be formed by a variety of techniques. The two distinct techniques described here are to plate up a silver bearing thick film conductor or gold based metallorganic coating. These both form well-adhered conductors in their own right after firing at a temperature in excess of 450° C., and while there are considerable benefits to overplating them with copper, it is not essential. Clearly however, the pins need to be plated or otherwise built up.

There are several alternative feasible methods to produce the region that forms the well-adhered main circuit conductors. For instance, while a direct bond copper circuit can include integrated pins as part of the process, an alternative is to start with a direct bond copper substrate that has not yet been broken out from the panel on which it was formed. These circuit traces would form members 2a and 5a as described herein. The pins can then be added to such a panel using the techniques described herein.

Another process that is frequently used to form circuits on ceramic is to coat the ceramic with electroless copper. A pattern of conductors is then built up on the coated substrate by selective electroplating. The electroless copper not covered by the added plating is then etched away and the tracks bonded to the substrate by firing in a slightly oxidising atmosphere at a temperature in excess of 1000° C. This circuit would then form the members 2a and 5a. The pins would then be added as described previously.

The temporarily adhered region has been described in terms of a silver loaded paint that is electrically conductive on heating or drying and has modest adhesive properties. Two alternatives are to use to use either an electroless deposition or a conductor formed by the thermal decomposition of metallorganic conductor. In the case of the electroless deposition, the adhesion between the ceramic and the conductor is poor. Thus, by combining an electroless deposition with a firing step with an electroless deposition without a firing step, the two distinct regions 2a and 2b can be defined. The metal deposited by the electroless process could be copper, nickel gold or silver.

It has already been demonstrated that region 2a could be formed by a metallorganic based process. Metallorganic conductors are formed from a blend of liquids. The main conductor element starts off as an organic salt of the metal dissolved in a suitable solvent. This is blended with small quantities of similar organic salts of base metals such as bismuth and chromium. This liquid, when combined with an appropriate binder, has a consistency suitable for screen printing or other deposition technique. After printing on the substrate, the substrate is heated. Initially the binder breaks down to leave a coating of just the blended metallorganic materials. Next, the salts themselves decompose to leave an alloy of the various metal elements coating the surface. Further heating causes the base metal materials partially to oxidise. The partially oxidised base metal reacts with both the ceramic and the main conductor material to bond the conductor to the ceramic. By varying the firing temperature and composition of the blend the conductor's adhesion can be varied. Thus by careful choice of blends either or both regions 2a and 2b can be formed by separate deposition steps. The conductor for either composition could be based on gold, silver, platinum, palladium or copper organic salts.

Both the electroless deposition and metallorganic deposition techniques can be chosen to form compatible conductors where the well adhered region is not compromised by the over coating with the material that does not bond well to the ceramic. This has important practical implications.

The electroless deposition and metallorganic deposition processes can both be used as compatible conductors to form region 2b when used in combination with a thick film conductor used to form region 2a.

I claim:

1 A process for the manufacturing of an electrical circuit board complete with some conductors that are in part attached to the circuit board and in part detached from the board comprising the following steps:
a) forming a structure that consists of an electrically insulating substrate processed to contain two mutually exclusive regions, these regions touching to provide electrical continuity over the insulating substrate where required, wherein one region is such that metal can be deposited on to it and be permanently bonded to the substrate and the other region is such that metal can be deposited on to it but the bond to the substrate is only temporary, the one region being fired at a temperature in excess of 450° C. to form a bond and the insulating substrate is an inorganic material capable of withstanding this firing temperature,
b) depositing metal selectively onto the two regions,
c) releasing the bond in the other region,
d) breaking the board into individual panels to leave the circuit board with a pattern of conductors in some places permanently bonded to the insulator and part of some of the conductors no longer attached to the substrate.

2. The process in accordance with claim 1, in which the insulator will allow metal to be deposited and permanently bonded to it and a coating material is applied selectively to the insulator with the property that metal can be deposited on it but the bond is temporary.

3. The process in accordance with claim 1, in which the insulating substrate will allow metal to be deposited on it but the bond is only temporary and a coating material is applied selectively to the insulating substrate with the property that after firing at a temperature in excess of 450° C. it will allow metal to be deposited onto it and the bond is permanent.

4. The process in accordance with claim 1, in which the conductors are not deposited directly onto the insulating substrate.

5. The process in accordance with claim 4, in which the one region is formed by coating with a material that is subsequently fired at a temperature in excess of 450° C. to allow metal to be deposited on it and is such that the bond is permanent and the other region is formed by coating with a material that will allow metal to be deposited on it and is such that the bond is temporary.

6. The process in accordance with claim 1, in which the one region is formed by coating with a material that is subsequently fired at a temperature in excess of 450° C. that will allow metal to be deposited on it and is such that the bond is permanent and the other region is formed by coating both the insulating substrate and the one region with a material that will allow metal to be deposited on it and is such that the bond is temporary where the temporary coating is in contact with the insulating substrate.

7. The process in accordance with claim 6, in which the bond is permanent where the metal is deposited onto the coating that is used to promote permanent adhesion.

8. The process in accordance with claim 1, in which the conductors that are permanently bonded to the insulating substrate are formed into a circuit pattern before the formation of the temporarily adhered layer.

9. The process in accordance with claim 1, in which the insulating substrate is a ceramic material.

10. The process in accordance with claim 1, in which the material used to form a permanent bond between the insulating substrate and deposited conductor is a thick film conductor.

11. The process in accordance with claim 1, in which the material used to form a permanent bond between the insulating substrate and deposited conductor is formed by a metallorganic material.

12. The process in accordance with claim 10, in which the thick film material is one of silver based or gold based.

13. The process in accordance with claim 10, in which the metallorganic material is one of silver based, gold based or platinum based.

14. The process in accordance with claim 1, in which the other region is formed by coating with a plastic material that is blended with metallic particles so that it is electrically conductive after drying or curing.

15. The process in accordance with claim 14, in which the plastic material is removed by dissolution in a suitable etchant or solvent in order to release the bond of the conductor to the insulating substrate at that point.

16. The process in accordance with claim 1, in which the material used to coat the substrate in the other region is based on electroless metal deposition.

17. The process in accordance with claim 16, in which the metal is one of copper, nickel, silver or gold.

18. The process in accordance with claim 1, in which the material used to coat the insulating substrate in the other region contains a metallorganic salt and the salt is heated to reduce the salt to the metal.

19. The process in accordance with claim 18, in which the metal is one of gold, silver, platinum, palladium or copper.

20. The process in accordance with claim 1, in which some part or parts of some of the conductors are not bonded to the circuit board.

21. The process in accordance with claim 20, in which the non-bonded region is outside the boundary of the circuit board.

22. The process in accordance with claim 1, in which the insulating substrate on which the integrated leads are formed is a pre-manufactured circuit board.

23. The process in accordance with claim 22, in which the pre-manufactured circuit board has outer layers and the process is applied to outer layers of the board.

24. The process in accordance with claim 1, comprising forming a circuit board in which some part or parts of at least one of the circuit conductors are not bonded to the insulating substrate of the circuit board.

25. The process in accordance with claim 24, in which part of at least one of the conductors overhangs the edge of the insulating substrate.
